(19) United States
(12) Patent Application Publication
(10) Pub. No.: US 2006/0213763 A1
(43) Pub. Date: Sep. 28, 2006

(54) Temperature control method and apparatus, and plasma processing apparatus

(75) Inventors: Masao Furuya, Nirasaki-shi (JP); Koji Ando, Nirasaki-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/389,046

(22) Filed: Mar. 27, 2006

Related U.S. Application Data
(60) Provisional application No. 60/666,704, filed on Mar. 31, 2005.

(30) Foreign Application Priority Data
Mar. 25, 2005 (JP) 2005-088984

(51) Int. Cl. C23C 14/32; C23C 14/00

(52) U.S. Cl. 204/192.1; 204/298.01

(57) ABSTRACT

A temperature control method and apparatus, and a plasma processing apparatus are provided. The temperature control method includes the steps of, during an idle state in which a substrate processing is not performed, controlling a temperature of a heat transfer medium in a circulation channel by a second heat exchanger and a heater to control a temperature of an electrode to be maintained at a predetermined set temperature, and when a high frequency power is applied to the electrode to start the substrate processing, reducing the temperature of the heat transfer medium below the set temperature of the electrode through the use of a first heat exchanger and the second heat exchanger to maintain the temperature of the electrode at the set temperature.

### FIELD OF THE INVENTION

The present invention relates to a temperature control method and apparatus, and a plasma processing apparatus.

### BACKGROUND OF THE INVENTION

In a manufacturing process of, e.g., a semiconductor device, a liquid crystal display device, or the like, e.g., an etching process is performed by using a plasma.

The etching process is performed generally by using a plasma processing apparatus. A parallel plate type having electrodes disposed respectively on an upper and a lower side is widely used as the plasma processing apparatus, and the parallel plate type plasma processing apparatus has, e.g., a processing chamber in which a high frequency power for generating a plasma is applied to a lower electrode having a substrate mounted thereon to generate the plasma between the lower and the upper electrode to etch a film on the substrate by using the plasma.

In the plasma processing apparatus, the temperature of the lower electrode is controlled to stabilize a substrate processing. For example, the plasma processing apparatus is provided with a circulation circuit of a coolant passing through an inside of the lower electrode and communicating with a chiller device. During the substrate processing, the coolant is supplied into the lower electrode and circulated therein to strictly control the temperature of the lower electrode (see, for example, Japanese Patent Laid-open Application No. 2002-168551).

Further, the temperature of the upper electrode needs to be controlled because the upper electrode is exposed to a plasma generation space, and the temperature of the upper electrode also influences an etching status. Therefore, it can be opted to control the temperature of the upper electrode by using the same chiller device as that used for cooling the lower electrode. However, since a strong electric power of a high frequency is applied to the upper electrode to generate the plasma, a large amount of heat is generated, and a thermal capacity is also high relatively to that of the lower electrode. On this account, a large amount of heat is generated by the upper electrode during a processing while its responsiveness to a temperature control coolant is poor.

Therefore, if the same chiller device used for the lower electrode is employed in the upper electrode, a long period of time is needed from the time the high frequency power is applied to the upper electrode to start the substrate processing till the time when the temperature of the upper electrode is stabilized. At this time, if the substrate processing is performed in a state while the temperature of the upper electrode is unstable, a result of the etching process becomes unstable. Accordingly, the start of the product substrate processing needs to be delayed to thereby deteriorate a throughput thereof.

### SUMMARY OF THE INVENTION

It is, therefore, an object of the present invention to provide a temperature control method and apparatus, and a plasma processing apparatus, in which a temperature of an electrode for generating a plasma can be stabilized from the start of a substrate processing.

In accordance with an aspect of the present invention, there is provided a temperature control method of an electrode, to which a high frequency power for generating a plasma in a plasma processing apparatus is applied, wherein the temperature control method is carried out by using a temperature control apparatus having: a circulation channel for circulating a heat transfer medium through an inside of the electrode and provided with; a first heat exchanger for performing a heat exchange of the heat transfer medium passed through the electrode by a sensible heat of a liquid coolant; a second heat exchanger for performing a heat exchange of the heat transfer medium passed through the first heat exchanger by a latent heat of a coolant; and a heater for heating the heat transfer medium supplied to the inside of the electrode, the temperature control method including the steps of: during an idle state in which a substrate processing is not performed, controlling a temperature of the heat transfer medium in the circulation channel by the second heat exchanger and the heater to control a temperature of the electrode to be maintained at a predetermined set temperature; and when the high frequency power is applied to the electrode to start the substrate processing, reducing the temperature of the heat transfer medium below the set temperature of the electrode through the use of the first heat exchanger and the second heat exchanger to maintain the temperature of the electrode at the set temperature.

Further, the term “idle state” used herein denotes a state wherein the substrate processing is not performed, e.g., during the changeover period from one substrate lot processing to another. And, the clause “when starting the substrate processing” means when the substrate processing is started from the idle state.

In accordance with the present invention, during the idle state wherein the substrate processing is not performed, the temperature of the electrode is controlled in advance to the predetermined set temperature by the second heat exchanger for performing the heat exchange by the latent heat of the coolant and the heater. And, when the substrate processing is started, the temperature of the heat transfer medium in the circulation channel is rapidly cooled by using both the first heat exchanger for performing the heat exchange by the sensible heat of the liquid coolant and the second heat exchanger.

By doing this, a heat generated by the high frequency power for generating the plasma is transferred out by the heat transfer medium so that the temperature of the electrode for generating the plasma is continuously maintained at the set temperature. As a result, the temperature of the electrode for generating the plasma is stabilized from the start of the substrate processing so that the product substrate processing can be started early.

The electrode for generating the plasma may be an upper electrode, and the plasma processing apparatus may include a lower electrode for mounting a substrate thereon, another high frequency power being applicable to the lower electrode, and a temperature difference ΔT between the set temperature of the upper electrode during the idle state and a target temperature of the heat transfer medium during the substrate processing may be set as, ΔT=k(aA+bB)×D/C, wherein k is a conversion factor from an electric power to a temperature; A is the high frequency power applied to the upper electrode, B is the high frequency power applied to the lower electrode; a is a factor showing a ratio of an influence of the high frequency power applied to the upper electrode, to an influence of all the high frequency powers, on the temperature of the upper electrode; b is a factor showing a ratio of an influence of the high frequency power applied to the lower electrode, to the influence of all the high frequency powers, on the temperature of the upper electrode; C is a processing time per substrate; and D is a high frequency power application time during the processing time C.

The circulation channel may be provided with a bypass passage for circulating the heat transfer medium so that the heat transfer medium bypasses the electrode for generating the plasma, and the temperature control method may further include the steps of: when the substrate processing is ended, increasing the temperature of the heat transfer medium by using the heater by circulating the heat transfer medium through the bypass passage; circulating the heat transfer medium so that the heat transfer medium passes through the inside of the electrode to stabilize the temperature of the heat transfer medium at the set temperature.

The temperature of the heat transfer medium may be stabilized at the set temperature by alternately performing a circulation of the heat transfer medium passing through the bypass passage, and a circulation of the heat transfer medium passing through the inside of the electrode. Further, the liquid coolant may be water.

In accordance with another aspect of the present invention, there is provided a temperature control apparatus of an electrode, to which a high frequency power for generating a plasma in a plasma processing apparatus is applied, including: a circulation channel for circulating a heat transfer medium through an inside of the electrode and provided with; a first heat exchanger for performing a heat exchange of the heat transfer medium passed through the electrode by a sensible heat of a liquid coolant; a second heat exchanger for performing a heat exchange of the heat transfer medium passed through the first heat exchanger by a latent heat of a coolant; a heater for heating the heat transfer medium supplied to the inside of the electrode; and a control unit, during an idle state in which a substrate processing is not performed, for controlling a temperature of the heat transfer medium in the circulation channel by the second heat exchanger and the heater to control a temperature of the electrode to be maintained at a predetermined set temperature, and when the high frequency power is applied to the electrode to start the substrate processing, for reducing the temperature of the heat transfer medium below the set temperature of the electrode through the use of the first heat exchanger and the second heat exchanger to maintain the temperature of the electrode at the set temperature.

The electrode for generating the plasma may be an upper electrode, and the plasma processing apparatus may include a lower electrode for mounting a substrate thereon, another high frequency power being applicable to the lower electrode, and the control unit may calculate to set a temperature difference ΔT between the set temperature of the upper electrode during the idle state and a target temperature of the heat transfer medium during the substrate processing as, ΔT=k(aA+bB)×D/C, wherein k is a conversion factor from an electric power to a temperature; A is the high frequency power applied to the upper electrode; B is the high frequency power applied to the lower electrode; a is a factor showing a ratio of an influence of the high frequency power applied to the upper electrode, to an influence of all the high frequency powers, on the temperature of the upper electrode; b is a factor showing a ratio of an influence of the high frequency power applied to the lower electrode, to the influence of all the high frequency powers, on the temperature of the upper electrode; C is a processing time per substrate; and D is a high frequency power application time during the processing time C.

The circulation channel may be provided with a bypass passage for circulating the heat transfer medium so that the heat transfer medium bypasses the electrode for generating the plasma, and the control unit, when the substrate processing is ended, may increase the temperature of the heat transfer medium by using the heater by circulating the heat transfer medium through the bypass passage, and may further, circulate the heat transfer medium so that the heat transfer medium passes through the inside of the electrode to stabilize the temperature of the heat transfer medium at the set temperature.

The control unit may alternately perform a circulation of the heat transfer medium passing through the bypass passage, and a circulation of the heat transfer medium passing through the inside of the electrode to stabilize the temperature of the heat transfer medium at the set temperature. Further, the liquid coolant may be water.

In accordance with still another aspect of the present invention, there is provided a plasma processing apparatus including: an electrode, to which a high frequency power for generating a plasma is applied; a circulation channel for circulating a heat transfer medium through an inside of the electrode and provided with; a first heat exchanger for performing a heat exchange of the heat transfer medium passed through the electrode by a sensible heat of a liquid coolant; a second heat exchanger for performing a heat exchange of the heat transfer medium passed through the first heat exchanger by a latent heat of a coolant; a heater for heating the heat transfer medium supplied to the inside of the electrode; and a control unit, during an idle state in which a substrate processing is not performed, for controlling a temperature of the heat transfer medium in the circulation channel by the second heat exchanger and the heater to control a temperature of the electrode to be maintained at a predetermined set temperature, and when the high frequency power is applied to the electrode to start the substrate processing, for reducing the temperature of the heat transfer medium below the set temperature of the electrode through the use of the first heat exchanger and the second heat exchanger to maintain the temperature of the electrode at the set temperature.

In the plasma processing apparatus, the electrode for generating the plasma may be an upper electrode, and the plasma processing apparatus may further include a lower electrode for mounting a substrate thereon, another high frequency power being applicable to the lower electrode, and the control unit may calculate to set a temperature difference ΔT between the set temperature of the upper electrode during the idle state and a target temperature of the heat transfer medium during the substrate processing as: ΔT=k(aA+bB)×D/C, wherein k is a conversion factor from an electric power to a temperature; A is the high frequency power applied to the upper electrode; B is the high frequency power applied to the lower electrode; a is a factor showing a ratio of an influence of the high frequency power applied to the upper electrode, to an influence of all the high frequency powers, on the temperature of the upper electrode; b is a factor showing a ratio of an influence of the high frequency power applied to the lower electrode, to the influence of all the high frequency powers, on the temperature of the upper electrode; C is a processing time per substrate; and D is a high frequency power application time during the processing time C.

In the plasma processing apparatus, the circulation channel may be provided with a bypass passage for circulating the heat transfer medium so that the heat transfer medium bypasses the electrode for generating the plasma, and the control unit, when the substrate processing is ended, may increase the temperature of the heat transfer medium by using the heater by circulating the heat transfer medium through the bypass passage, and may further, circulate the heat transfer medium so that the heat transfer medium passes through the inside of the electrode to stabilize the temperature of the heat transfer medium at the set temperature.

In the temperature control apparatus, the control unit may alternately perform a circulation of the heat transfer medium passing through the bypass passage, and a circulation of the heat transfer medium passing through the inside of the electrode to stabilize the temperature of the heat transfer medium at the set temperature. Further, the liquid coolant may be water.

In accordance with the present invention, the temperature of the upper electrode can be stabilized from the start of the substrate processing and a product substrate processing can be performed from the start so that a throughput can be improved.

### BRIEF DESCRIPTION OF THE DRAWINGS

The above and other objects and features of the present invention will become apparent from the following description of preferred embodiment given in conjunction with the accompanying drawings, in which:

FIG. 1 offers an explanatory diagram schematically showing a configuration of a plasma processing apparatus and a temperature control apparatus in accordance with a preferred embodiment of the present invention;

FIG. 2 shows a graph showing temperature variations of an upper electrode and a brine from an idle state to a lot processing, and an on and off timing of the upper electrode;

FIG. 3 is a graph showing the temperature variations of the upper electrode and the brine after the lot processing is ended, the on and off timing of the upper electrode, and a conversion of a brine circulation; and

FIG. 4 depicts an explanatory diagram showing a processing time and a high frequency power application time in case a substrate processing is performed in a plurality of steps.

### DETAILED DESCRIPTION OF THE PREFERRED EMBODIMENTS

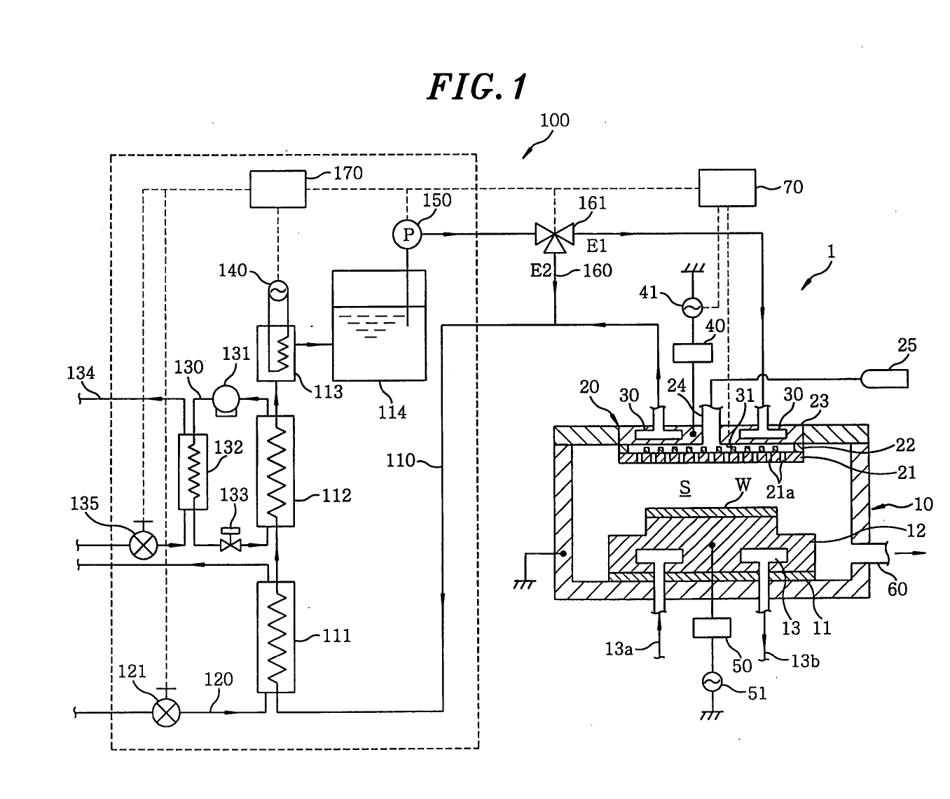

Hereinafter, a preferred embodiment of the present invention will be described. FIG. 1 is an explanatory diagram schematically showing a configuration of a plasma processing apparatus 1 and a temperature control apparatus 100 in accordance with the present preferred embodiment.

The plasma processing apparatus 1 is a capacitively coupled plasma etching apparatus having a parallel plate type electrode scheme. The plasma processing apparatus 1 includes a substantially cylindrical processing vessel 10. And a processing space S is formed in the processing vessel 10. The processing vessel 10 is made of, for example, an aluminum alloy, and an inner wall surface thereof is coated with an alumina film or an yttrium oxide film. The processing vessel 10 is grounded.

A susceptor 12 is provided on a central bottom portion inside the processing vessel 10, with an insulating plate 11 interposed therebetween. The susceptor 12 has a substantially cylindrical shape on which a substrate W can be mounted. The susceptor 12 is made of, for example, the aluminum alloy, and serves as a lower electrode of the parallel plate type electrode scheme.

An annular coolant chamber 13 is formed in the susceptor 12. The coolant chamber 13 communicates with a chiller unit (not shown) installed outside the processing vessel 10, through lines 13a and 13b. A coolant is supplied to the coolant chamber 13 to be circulated through the lines 13a and 13b to thereby control a temperature of the substrate W on the susceptor 12.

An upper electrode 20 facing the susceptor 12 is installed above the susceptor 12 to generate a plasma. A plasma generating space is formed between the susceptor 12 and the upper electrode 20.

The upper electrode 20 has a three-layered structure including, for example, an electrode plate 21, a dispersion plate 22 and a ceiling plate 23 in that order. A gas supply line 24 is connected to, for example, a central portion of the uppermost ceiling plate 23 to introduce an etching gas as a processing gas into the processing space S. The gas supply line 24 is connected to a processing gas supply source 25.

The dispersion plate 22 having, for example, a substantially cylindrical shape is arranged underneath the ceiling plate 23, so that the processing gas introduced through the gas supply line 24 can be uniformly dispersed. Underneath the dispersion plate 22, for example, the electrode plate 21 facing the substrate W on the susceptor 12 is provided. Formed on the electrode plate 21 is a plurality of gas injection openings 21a, through which the processing gas dispersed by the dispersion plate 22 can be uniformly jetted.

An annular flow path 30 through which a heat transfer medium, e.g., a brine, passes is formed in, e.g., the ceiling plate 23 of the upper electrode 20. The flow path 30 is included as a part of a circulation channel 110 of the temperature control apparatus 100 to be described later. Further, a temperature sensor 31 for measuring a temperature of the upper electrode 20 as a control target temperature of a temperature control is provided in, e.g., the dispersion plate 22.

A first high frequency power supply 41 is electrically connected to the upper electrode 20 via a matching unit 40. The first high frequency power supply 41 is capable of producing a high frequency power having a frequency higher than, for example, about 40 MHz, namely, 60 MHz. The high frequency power is supplied to the upper electrode 20 from the first high frequency power supply 41, to thereby generate the plasma in the processing space S.

A second high frequency power supply 51 is electrically connected to the susceptor 12 via a matching unit 50. The second high frequency power supply 51 is capable of producing a high frequency power having a frequency in a range of, for example, 2 MHz to 20 MHz, namely 20 MHz. The high frequency power is supplied to the susceptor 12 from the second high frequency power supply 51, to thereby induce charged particles in the processing space S to be brought into a side of the substrate W.

A gas exhaust pipe 60 communicated with a gas exhaust unit (not shown) is connected to a side surface of the processing vessel 10. By exhausting a gas through the gas exhaust pipe 60, it is possible to reduce a pressure in the processing vessel 10 to a desired vacuum level.

The plasma processing apparatus 1 is provided with a apparatus control unit 70 which controls operations of various components, for example, the processing gas supply source 25, the first high frequency power supply 41, the second high frequency power supply 51, and the like, needed to perform an etching process. Further, a measurement result obtained by using the temperature sensor 31 can be outputted to the apparatus control unit 70.

In a plasma etching process performed by using the plasma processing apparatus 1, first of all, the substrate W is adsorptively supported on the susceptor 12. Next, a pressure in the processing space S is reduced to a predetermined level by exhausting a gas through, for example, the gas exhaust pipe 60. The processing gas is then supplied into the processing space S through the upper electrode 20. A high frequency power is supplied to the upper electrode 20 from the first high frequency power supply 41, and thus, the processing gas in the processing space S is turned into a plasma.

Further, another high frequency power is supplied to the susceptor 12 from the second high frequency power supply 51, and thus, charged particles of the plasma are induced toward the substrate W. As a result, a film on the substrate W is etched by an action of the plasma. The etched substrate W is unloaded from the processing vessel 10, and then, a next substrate W is loaded thereinto.

Hereinafter, a description will be made on the temperature control apparatus 100 for performing a temperature control of the upper electrode 20 of the plasma processing apparatus 1.

The temperature control apparatus 100 includes a circulation channel 110 through which the brine is circulated to pass through an inside of the upper electrode 20; a first heat exchanger 111 provided at the circulation channel 110, performing a heat exchange with the brine which flows out from the upper electrode 20 by a sensible heat of water used as a liquid coolant; a second heat exchanger 112 provided at the circulation channel 110, performing a heat exchange with the brine by a latent heat; an electric heater 113 for heating the brine; and a tank 114 for storing the brine before the brine is supplied to the upper electrode 20.

And, the brine is a liquid heat exchange medium, e.g., a silicone oil, a fluorine-based liquid, an ethylene glycol or the like. The first heat exchanger 111, the second heat exchanger 112, the electric heater 113, and the tank 114 are connected in series along the circulation channel 110. Accordingly, the brine can be circulated through the upper electrode 20, the first heat exchanger 111, the second heat exchanger 112, the electric heater 113, and the tank 114 in that order (a circulation path E1 shown in FIG. 1).

A passageway 120 of a second coolant side is connected to the first heat exchanger 111 to introduce, e.g., the water used as a second coolant into the first heat exchanger 111 and discharge it therefrom. An upstream side of the passageway 120 is connected to, e.g., a water supply unit (not shown). By having the water to flow through the passageway 120, the brine in the circulation channel 110 can be cooled in the first heat exchanger 111 by the sensible heat of the water. The passageway 120 is provided with an opening/closing valve 121. By switching opening and closing of the opening/closing valve 121, a cooling of the brine performed by the water of the first heat exchanger 111 can be made to be on or off.

The second heat exchanger 112 is an evaporator, and can cool the brine in the circulation channel 110 by the latent heat of, e.g., a flon substitute, e.g., a hydro fluorocarbon (HFC), serving as a second coolant. A circulation circuit 130 included as a part of a chiller is connected to the second heat exchanger 112. The circulation circuit 130 is provided with a compressor 131, a condenser 132 and an expansion valve 133. A supply passageway 134 of, e.g., a cooling water serving as a third coolant is connected to the condenser 132. The supply passageway 134 is provided with, e.g., a flow rate control valve 135. It is possible to control a cooling capacity of the second heat exchanger 112 with the flow rate control valve 135 which controls a supply amount of the cooling water into the condenser 132.

The electric heater 113 can generate a heat by a power supplied from, e.g., a heater power supply 140 to heat the brine in the circulation channel 110.

The tank 114 is provided with, e.g., a pump 150. The pump can force-feed the brine stored in the tank 114 to the upper electrode 20.

The circulation channel 110, e.g., between the tank 114 and the upper electrode 20 is provided with a bypass passage 160 bypassing the upper electrode 20 to lead the brine which is force-fed from the tank 114 to the first heat exchanger 111. By the bypass passage 160, the brine can be circulated in an order of the bypass passage 160, the first heat exchanger 111, the second heat exchanger 112, the electric heater 113, the tank 114, and the bypass passage 160 (a circulation path E2 shown in FIG. 1). A three-way valve 161 is provided at a junction node of the bypass passage 160. By the three-way valve 161, the circulation path E2 passing through the bypass passage 160 which does not pass the upper electrode 20 and the circulation path E1 passing through the upper electrode 20 can be switched from one to another.

The temperature control apparatus 100 is provided with a control unit 170 which controls operations of various components, e.g., the opening/closing valve 121 of the first heat exchanger 111, the flow rate control valve 135 of the second heat exchanger 112, the heater power supply 140 of the electric heater 113, the pump 150 of the tank 114, the three-way valve 161 and the like, all of which are involved in performing the temperature control of the upper electrode 20. The control unit 170 can communicate with the apparatus control unit 70 of the plasma processing apparatus 1, and control operations of the components based on information from the apparatus control unit 70.

Hereinafter, a description will be made on a temperature control process of the upper electrode 20 performed by using the temperature control apparatus 100.

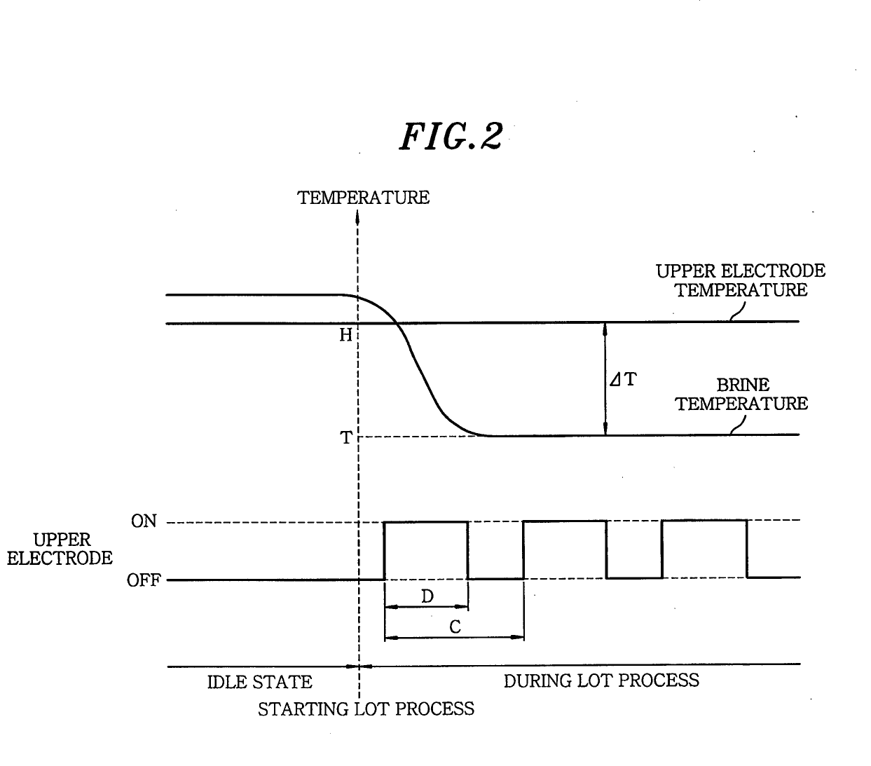

In the plasma processing apparatus 1, during an idle state before a substrate lot processing is started, temperature of the brine is controlled in the circulation path E1 of the circulation channel 110 such that the temperature of the upper electrode 20 is controlled to be maintained at a predetermined set temperature H as shown in FIG. 2. The set temperature H is a temperature that stabilizes the upper electrode 20 during the process.

For the temperature control, first of all, a temperature measurement result obtained by using the temperature sensor 31 of the upper electrode 20 shown in FIG. 1 is outputted to the apparatus control unit 70, and then, to the control unit 170 therefrom. The control unit 170 controls the flow rate control valve 135 of the second heat exchanger 112 and the heater power supply 140 of the electric heater 113 based on the temperature measurement result to control the temperature of the brine in the circulation channel 110 such that the temperature of the upper electrode 20 can be maintained at the set temperature H.

At this time, the opening/closing valve 121 of the first heat exchanger 111 is closed so that the temperature of the brine is controlled by the second heat exchanger 112 and the electric heater 113. That is, the brine is cooled by the latent heat of the flon substitute of the second heat exchanger 112. During the idle state, the temperature of the brine in the circulation channel 110 is controlled to be kept at a temperature a little higher than the set temperature H to compensate thermal dissipation, for example.

Further, in the plasma processing apparatus 1, when the substrate lot processing is started after the idle state is ended, a target temperature T of the brine in the circulation channel 110 shown in FIG. 2 is set. The target temperature T of the brine is set, e.g., when process start information of the apparatus control unit 70 is inputted to the control unit 170.

The target temperature T is lower than the set temperature H of the upper electrode 20, and a temperature difference ΔT between the set temperature H and the target temperature T can be calculated as:
ΔT=k(aA+bB)×D/C Eq. 1

In Eq. 1, k is a conversion factor from an electric power to a temperature; A is the high frequency power applied to the upper electrode 20; and B is the high frequency power applied to the susceptor 12. And, a is a factor showing an extent of an influence of the high frequency power applied to the upper electrode 20, relative to the influence of all the high frequency powers applied to both the upper and lower electrodes, on the temperature of the upper electrode 20; and b is a factor showing an extent of an influence of the high frequency power applied to the susceptor 12, relative to the influence of all the high frequency powers applied to both the upper and lower electrodes, on the temperature of the upper electrode 20.

Moreover, C is a processing time per substrate; and D is a high frequency power application time during the processing time C. As shown in FIG. 2, the processing time C is a time spent for one substrate, e.g., a total time spent in applying the high frequency power and replacing the substrate W. By the control unit 170, the temperature difference ΔT is calculated, and the target temperature T is set.

Once the temperature difference ΔT is calculated to set the target temperature T, the opening/closing valve 121 of the first heat exchanger 111 shown in FIG. 1 is opened, the brine in the circulation channel 110 is rapidly cooled by the sensible heat of the water of the first heat exchanger 111, and the latent heat of the flon substitute of the second heat exchanger 112, to stabilize the temperature of the brine at the target temperature T. When the substrate lot processing is started, the high frequency power for generating the plasma is applied to the upper electrode 20, and thus generated heat is transferred out by the cooled brine so that the temperature of the upper electrode 20 is maintained at the set temperature H as shown in FIG. 2.

After that, until the substrate lot processing is ended, the temperature of the brine is maintained at the target temperature T so that the temperature of the upper electrode 20 is maintained at the set temperature H. It is preferable that a timing at which the brine is started to be rapidly cooled by the first heat exchanger 111 and the second heat exchanger 112 is, for example, when the high frequency power is applied to the upper electrode 20 for the first time or just before that time.

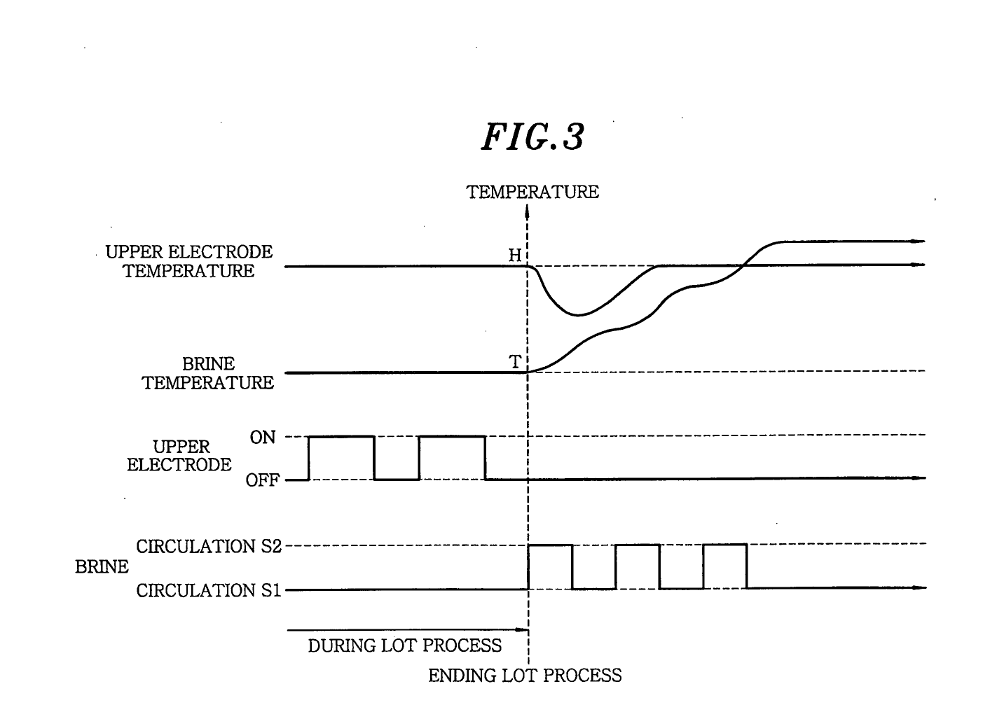

Thereafter, when the lot processing is ended, a flow path of the bypass passage 160 side of the three-way valve 161 shown in FIG. 1 is opened, and thus, the brine is circulated while bypassing the upper electrode 20 (circulation path E2). At this time, for example, the respective cooling performances of the first heat exchanger 111 and the second heat exchanger 112 are stopped, and thus, the brine is heated by the electric heater 113 as shown in FIG. 3. Thereafter, by the three-way valve 161, the flow path is switched from the above-described flow path of the bypass passage 160 side to a flow path of the upper electrode 20 side so that the heated brine is circulated through the flow path passing through the inside of the upper electrode 20 (circulation path E1).

By the three-way valve 161, the flow path is intermittently and alternately switched between the circulation path E1 of the brine passing through the upper electrode 20 and the circulation path E2 passing through a shortcut while bypassing the upper electrode 20. Accordingly, the temperature of the brine is returned to the temperature of the idle state. Further, the temperature of the upper electrode 20 dropped just after the lot processing is ended is recovered to the set temperature H.

In accordance with the preferred embodiment, during the idle state, the temperature of the upper electrode 20 is controlled in advance to the set temperature H at which its temperature is stabilized, and then, when the process of the substrate W is started, the brine is rapidly cooled to the target temperature T by the first heat exchanger 111 and the second heat exchanger 112.

Because the cooling by the first heat exchanger 111 is performed by using the water having a high thermal capacity, the upper electrode 20 having a high thermal capacity and generating a large amount of heat can be rapidly cooled to thereby suppress a rise of the temperature of the upper electrode 20 due to a high frequency power application when the process is started. As a result, since the temperature of the upper electrode 20 is maintained at the set temperature H after the process of the substrate W is started, a process of a product substrate W can be performed from the beginning.

Further, a cooling temperature ΔT of the brine is calculated by considering the respective high frequency powers applied to the upper electrode 20 and the susceptor 12, and a ratio of the influence of each high frequency power on the temperature of the upper electrode 20 by using Eq. 1. Accordingly, an accurate temperature for maintaining the set temperature H of the upper electrode 20 can be calculated.

When the lot processing is ended, the brine is circulated through the shortcut passing through the bypass passage 160 so that the temperature of the brine is rapidly increased. Next, the bypass passage 160 is closed so that the brine is flowed through the upper electrode 20. And then, because the above is repeated alternately, the temperature of the upper electrode 20 dropped for a while after the substrate processing is ended can be recovered to the set temperature H in a short time.

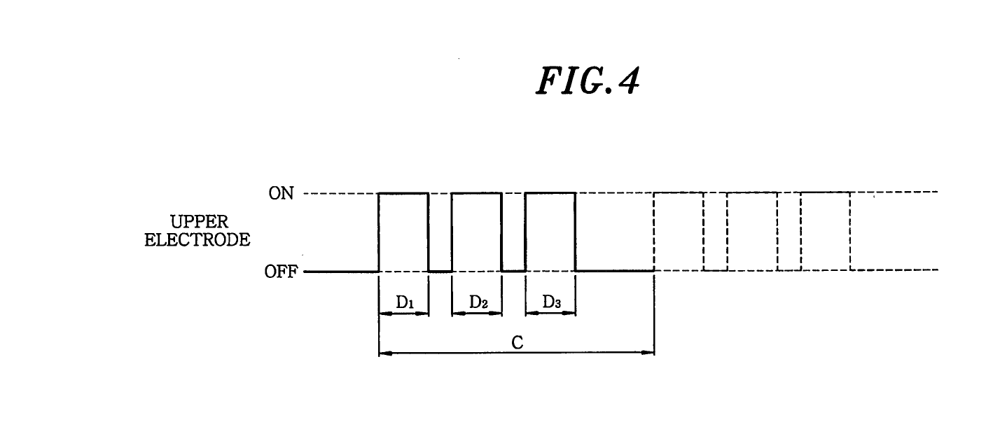

In the plasma processing apparatus 1, a plurality of etching processes may be successively performed on a single substrate W. At this time, for the substrate W, the high frequency power is applied to the upper electrode 20 a plurality of times. In this case, in calculating the cooling temperature ΔT of the brine by Eq. 1, the high frequency power application time D for the processing time C per substrate W, e.g., as shown in FIG. 4, can be calculated by summing all of application times D1 to D3 of the respective high frequency powers.

Further, in case a corresponding high frequency power output of each time period is different from one another, each of the high frequency power A of the upper electrode 20 and the high frequency power B of the susceptor 12 may be substituted with a corresponding average value of high frequency powers applied over a plurality of times.

While the preferred embodiment of the present invention has been shown and described in conjunction with the accompanying drawings, the present invention is not limited thereto. It will be understood by those skilled in the art that various changes and modifications may be made without departing from the scope of the invention as defined in the following claims, and they are embraced in the technical scope of the present invention. For example, although the above-described preferred embodiment has described the case of controlling the temperature of the upper electrode 20 of the plasma processing apparatus 1 for performing the etching process, the present invention can be applied to a case of controlling a temperature of an upper electrode of a plasma processing apparatus for performing a plasma processing other than the etching process, e.g., a film forming process.

Further, the temperature controlled electrode may not be limited to the upper electrode, and may be the lower electrode if it is an electrode for generating the plasma. Still further, as the liquid coolant of the first heat exchanger 111, the water may be used one time, or may be circulated and temperature controlled so that its temperature is constantly maintained. In the latter case, the brine can be used as the liquid coolant. Further, the coolant of the second heat exchanger 112 may be ammonia, air, carbon dioxide, a hydrocarbon-based gas, or the like, other than the HFC (hydro fluorocarbon) among the flon substitutes.

What is claimed is:

1. A temperature control method of an electrode, to which a high frequency power for generating a plasma in a plasma processing apparatus is applied, wherein the temperature control method is carried out by using a temperature control apparatus including:
a circulation channel for circulating a heat transfer medium through an inside of the electrode and provided with;
a first heat exchanger for performing a heat exchange of the heat transfer medium passed through the electrode by a sensible heat of a liquid coolant;
a second heat exchanger for performing a heat exchange of the heat transfer medium passed through the first heat exchanger by a latent heat of a coolant; and
a heater for heating the heat transfer medium supplied to the inside of the electrode,
the temperature control method comprising the steps of:
during an idle state in which a substrate processing is not performed, controlling a temperature of the heat transfer medium in the circulation channel by the second heat exchanger and the heater to control a temperature of the electrode to be maintained at a predetermined set temperature; and
when the high frequency power is applied to the electrode to start the substrate processing, reducing the temperature of the heat transfer medium below the set temperature of the electrode through the use of the first heat exchanger and the second heat exchanger to maintain the temperature of the electrode at the set temperature.

2. The temperature control method of claim 1, wherein the electrode for generating the plasma is an upper electrode, and
the plasma processing apparatus includes a lower electrode for mounting a substrate thereon, another high frequency power being applicable to the lower electrode, and
a temperature difference ΔT between the set temperature of the upper electrode during the idle state and a target temperature of the heat transfer medium during the substrate processing is set as:
ΔT=k(aA+bB)×D/C,
wherein k is a conversion factor from an electric power to a temperature; A is the high frequency power applied to the upper electrode; B is the high frequency power applied to the lower electrode; a is a factor showing a ratio of an influence of the high frequency power applied to the upper electrode, to an influence of all the high frequency powers, on the temperature of the upper electrode; b is a factor showing a ratio of an influence of the high frequency power applied to the lower electrode, to the influence of all the high frequency powers, on the temperature of the upper electrode; C is a processing time per substrate; and D is a high frequency power application time during the processing time C.

3. The temperature control method of claim 1, wherein the circulation channel is provided with a bypass passage for circulating the heat transfer medium so that the heat transfer medium bypasses the electrode for generating the plasma, and further comprising the steps of:
when the substrate processing is ended, increasing the temperature of the heat transfer medium by using the heater by circulating the heat transfer medium through the bypass passage;
circulating the heat transfer medium so that the heat transfer medium passes through the inside of the electrode to stabilize the temperature of the heat transfer medium at the set temperature.

4. The temperature control method of claim 3, wherein the temperature of the heat transfer medium is stabilized at the set temperature by alternately performing a circulation of the heat transfer medium passing through the bypass passage, and a circulation of the heat transfer medium passing through the inside of the electrode.

5. The temperature control method of claim 1, wherein the liquid coolant is water.

6. A temperature control apparatus of an electrode, to which a high frequency power for generating a plasma in a plasma processing apparatus is applied, comprising:
a circulation channel for circulating a heat transfer medium through an inside of the electrode and provided with;
a first heat exchanger for performing a heat exchange of the heat transfer medium passed through the electrode by a sensible heat of a liquid coolant;
a second heat exchanger for performing a heat exchange of the heat transfer medium passed through the first heat exchanger by a latent heat of a coolant;
a heater for heating the heat transfer medium supplied to the inside of the electrode; and
a control unit, during an idle state in which a substrate processing is not performed, for controlling a temperature of the heat transfer medium in the circulation channel by the second heat exchanger and the heater to control a temperature of the electrode to be maintained at a predetermined set temperature, and when the high frequency power is applied to the electrode to start the substrate processing, for reducing the temperature of the heat transfer medium below the set temperature of the electrode through the use of the first heat exchanger and the second heat exchanger to maintain the temperature of the electrode at the set temperature.

7. The temperature control apparatus of claim 6, wherein the electrode for generating the plasma is an upper electrode, and
the plasma processing apparatus includes a lower electrode for mounting a substrate thereon, another high frequency power being applicable to the lower electrode, and
the control unit calculates to set a temperature difference ΔT between the set temperature of the upper electrode during the idle state and a target temperature of the heat transfer medium during the substrate processing as:
ΔT=k(aA+bB)×D/C,
wherein k is a conversion factor from an electric power to a temperature; A is the high frequency power applied to the upper electrode; B is the high frequency power applied to the lower electrode; a is a factor showing a ratio of an influence of the high frequency power applied to the upper electrode, to an influence of all the high frequency powers, on the temperature of the upper electrode; b is a factor showing a ratio of an influence of the high frequency power applied to the lower electrode, to the influence of all the high frequency powers, on the temperature of the upper electrode; C is a processing time per substrate; and D is a high frequency power application time during the processing time C.

8. The temperature control apparatus of claim 6, wherein the circulation channel is provided with a bypass passage for circulating the heat transfer medium so that the heat transfer medium bypasses the electrode for generating the plasma, and
the control unit, when the substrate processing is ended, increases the temperature of the heat transfer medium by using the heater by circulating the heat transfer medium through the bypass passage, and further,
circulates the heat transfer medium so that the heat transfer medium passes through the inside of the electrode to stabilize the temperature of the heat transfer medium at the set temperature.

9. The temperature control apparatus of claim 8, wherein the control unit alternately performs a circulation of the heat transfer medium passing through the bypass passage, and a circulation of the heat transfer medium passing through the inside of the electrode to stabilize the temperature of the heat transfer medium at the set temperature.

10. The temperature control apparatus of claim 6, wherein the liquid coolant is water.

11. A plasma processing apparatus comprising:
an electrode, to which a high frequency power for generating a plasma is applied;
a circulation channel for circulating a heat transfer medium through an inside of the electrode and provided with;
a first heat exchanger for performing a heat exchange of the heat transfer medium passed through the electrode by a sensible heat of a liquid coolant;
a second heat exchanger for performing a heat exchange of the heat transfer medium passed through the first heat exchanger by a latent heat of a coolant;
a heater for heating the heat transfer medium supplied to the inside of the electrode; and
a control unit, during an idle state in which a substrate processing is not performed, for controlling a temperature of the heat transfer medium in the circulation channel by the second heat exchanger and the heater to control a temperature of the electrode to be maintained at a predetermined set temperature, and when the high frequency power is applied to the electrode to start the substrate processing, for reducing the temperature of the heat transfer medium below the set temperature of the electrode through the use of the first heat exchanger and the second heat exchanger to maintain the temperature of the electrode at the set temperature.

12. The plasma processing apparatus of claim 11, wherein the electrode for generating the plasma is an upper electrode, and
the plasma processing apparatus further comprises a lower electrode for mounting a substrate thereon, another high frequency power being applicable to the lower electrode, and
the control unit calculates to set a temperature difference ΔT between the set temperature of the upper electrode during the idle state and a target temperature of the heat transfer medium during the substrate processing as:
ΔT=k(aA+bB)×D/C,
wherein k is a conversion factor from an electric power to a temperature; A is the high frequency power applied to the upper electrode; B is the high frequency power applied to the lower electrode; a is a factor showing a ratio of an influence of the high frequency power applied to the upper electrode, to an influence of all the high frequency powers, on the temperature of the upper electrode; b is a factor showing a ratio of an influence of the high frequency power applied to the lower electrode, to the influence of all the high frequency powers, on the temperature of the upper electrode; C is a processing time per substrate; and D is a high frequency power application time during the processing time C.

13. The plasma processing apparatus of claim 11, wherein the circulation channel is provided with a bypass passage for circulating the heat transfer medium so that the heat transfer medium bypasses the electrode for generating the plasma, and
the control unit, when the substrate processing is ended, increases the temperature of the heat transfer medium by using the heater by circulating the heat transfer medium through the bypass passage, and further,
circulates the heat transfer medium so that the heat transfer medium passes through the inside of the electrode to stabilize the temperature of the heat transfer medium at the set temperature.

14. The temperature control apparatus of claim 13, wherein the control unit alternately performs a circulation of the heat transfer medium passing through the bypass passage, and a circulation of the heat transfer medium passing through the inside of the electrode to stabilize the temperature of the heat transfer medium at the set temperature.

15. The temperature control apparatus of claim 11, wherein the liquid coolant is water.
